(19) United States
(12) Patent Application Publication
(10) Pub. No.: US 2005/0184752 A1
(43) Pub. Date: Aug. 25, 2005

(54) Apparatus and method for automotive bus switching protection

(76) Inventor: Alexandre Pierre Palus, Houston, TX (US)

Correspondence Address: TEXAS INSTRUMENTS INCORPORATED, P O BOX 655474, M/S 3999, DALLAS, TX, 75265, US

(21) Appl. No.: 10/784,722

(22) Filed: Feb. 23, 2004

(51) Int. Cl. H03K 19/003

(52) U.S. Cl. 326/9

(57) ABSTRACT

In order to insure accurate transmission of logic signal, the logic signal and its complement are transmitted between a central processing unit and a peripheral unit. The logic signal and its complement are both used to reconstruct the original logic signal. When an error has occurred in either the logic signal or its complement, an EXCEPTION signal is generated.

This application claims priority under 35 USC §119(e)(1) of Provisional Application No. 60/446,810 (TI-35999P) filed Feb. 21, 2003.

### FIELD OF THE INVENTION

This invention relates generally to data processing systems and, more particularly, to the transfer of signals between a central processing unit and associated peripheral units. The present invention is particularly relevant to automotive data processing systems.

### BACKGROUND OF THE INVENTION

For reasons of control and safety, data processing systems in automotive systems have become increasingly sophisticated. A central processing unit monitors sensors that measure parameters of the automotive unit operation. For example, the central processing unit can monitor signals identifying the rotation of the tires in the automotive unit and can provide control signals to relevant automotive components, for example in an anti-skid mode of operation. Similarly, sensors can provide the signals that result in the deployment of an air-bag. As consumers demand ever increasing capabilities, such as collision avoidance systems, the importance and complexity of the automotive data processing system can only increase.

Referring to FIG. 1, a typical system 10 for exchanging signals between a central processing unit 11 and a plurality of peripheral units, peripheral unit #1 121 through peripheral unit #N 12N. Each peripheral unit M 12M receives signals from the central processing unit via bus 14M and transmits signals to the central processing unit 11 via bus 15M.

By way of example, the peripheral unit could be a sensor system monitoring the rotation of a wheel. The central processing unit sends initialization and time base signals to the sensor peripheral and receives signals indicative of the wheel rotation. The central processing unit can then process the signals according to a program.

In the automotive environment, the possibility of incorrect transmission of logic signals can potentially result in dangerous operation of the vehicle. In addition, because the length of conductors between a central processing unit and a peripheral unit is relatively long, the possibility of error generation in a transmitted signal is increased.

A need has therefore been felt for apparatus and an associated method having the feature that logic signals can be accurately transmitted in an automotive environment. It would be yet another feature of the apparatus and associated method to provide a signal indicating when a logic signal has been inaccurately transmitted. It would be a more particular feature of the apparatus and associated method to transmit both a logic signal and its complement to insure accurate transmission of the logic signal.

### SUMMARY OF THE INVENTION

The aforementioned and other features are accomplished, according to the present invention, by providing as part of a bus coupling a peripheral unit and the central processing unit, at least two associated conductors to transmitting a single signal. One of the associated conductors has a logic signal applied thereto. The associated conductor has complement logic signal applied thereto. At the output of the bus, the associated conductors are applied to a verification unit that verifies that the two associated conductors carry complementary logic signals. When the presence of complementary logic signals on the two associated conductors can not be verified, an exception condition is identified and appropriate response is taken by the data processing system.

Other features and advantages of the present invention will be more clearly understood upon reading of the following description and the accompanying drawings and claims.

### BRIEF DESCRIPTION OF THE DRAWINGS

FIG. 1 is a block diagram of a data processing system having particular applicability to automotive data processing unit according to the prior art.

FIG. 2 is a block diagram of technique for distribution of signals in an automotive data processing system according to the prior art.

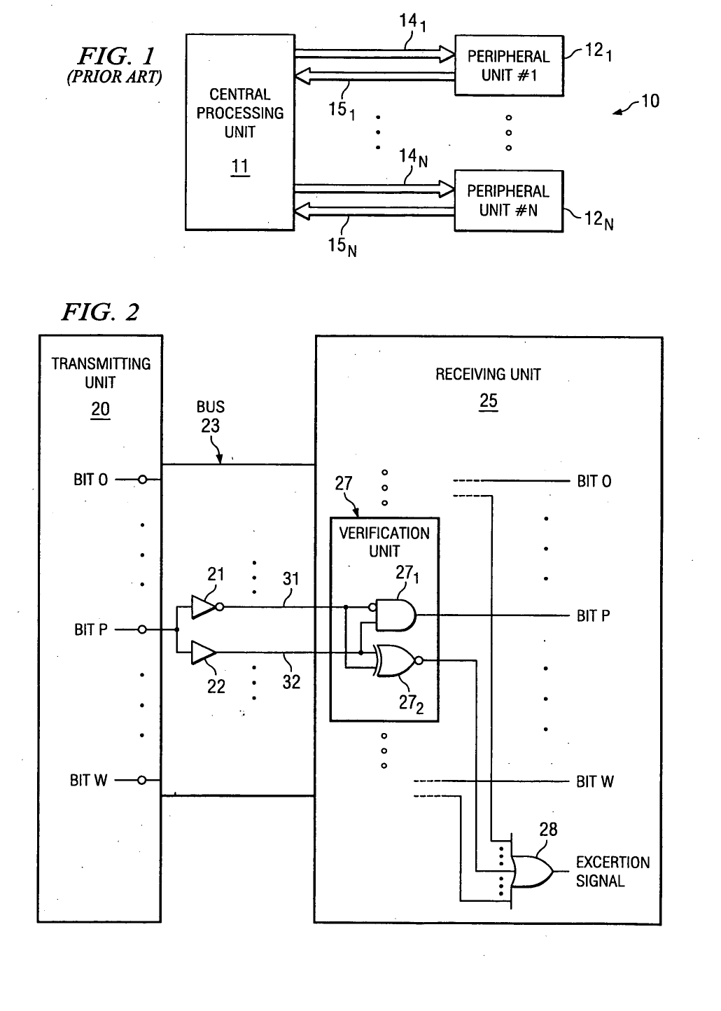

### DESCRIPTION OF THE PREFERRED EMBODIMENT

### 1. Detailed Description of the Drawings

Referring to FIG. 2, the technique for transferring logic signals from a signal transmitting unit 20 to a signal receiving unit 25 according to the present invention is shown. The signals from transmitting unit 20 to receiving unit 25 are transferred by bus 23. At least one signal, bit P, is transferred using the present invention. Signal bit P is applied to an input terminal of inverting amplifier 21 and amplifier 22. While inverting amplifier 21 and amplifier 22 are shown as being included in bus 23, it will be clear these amplifiers can be part of the transmitting unit 20 or can be interposed between transmitting unit 20 and the bus 23. The output terminal of inverting amplifier 21 is applied to conductor 31, while the output terminal of amplifier 22 is coupled to associated conductor 32, the associated conductors 31 and 32 being part of bus 23. The associated conductors 31 and 32 are applied to the receiving unit 25 and, more particularly, to verification unit 27. Within verification unit 27, conductor 31 is coupled to an inverting input terminal of logic AND gate 271, while conductor 32 is coupled to an input terminal of logic AND gate 27. The output terminal logic AND gate is the transferred logic bit P. The conductor 31 and the conductor 32 are applied to input terminals of logic EXCLUSIVE NOR gate 272. The output terminal of logic EXCLUSIVE NOR gate 272 is coupled to an input terminal of logic OR gate 28. The output terminals of the logic EXCLUSIVE NOR gate associated with each transferred logic bit is applied to logic OR gate 28. The output terminal of logic OR gate 28 provides the EXCEPTION signal.

### 2. Operation of the Preferred Embodiment

The operation of the present invention can be understood as follows. The associated conductors carry the logic state signal and the complementary logic state signals respectively. In the case of no error being generated, the logic AND gate will reconstitute the transferred logic signal. The logic EXCLUSIVE NOR gate, receiving different logic state signals, generate a logic 0 state signal. This logic 0 state signal, when applied to the logic OR gate will not result in the generation of an EXCEPTION signal. When an error occurs in the transfer of a logic signal, one of the logic signals on the associated conductor pair will change logic states. In this situation, the logic signals on both associated conductors are the same. The output signal of the logic AND gate will be a logic 0. Therefore, the error can not write a logic 1 by mistake. In a system in which a logic 0 is considered inactive data or is zero dominant, the system is protected from error. Because the same logic state signals are applied to the terminals of logic EXCLUSIVE NOR gate, the output signal of the logic EXCLUSIVE NOR gate will be a logic 1 signal indicating a signal transmission error. The output signals from the logic EXCLUSIVE NOR gates associated with the transmission of each logic bit signals are applied to the logic OR gate. A logic 1 signal from any of the verification units will result in an EXCEPTION signal, the EXCEPTION signal indicating incorrect signal transmission for one of the group of logic bits.

While the invention has been described with respect to the embodiments set forth above, the invention is not necessarily limited to these embodiments. Accordingly, other embodiment variations, and improvements not described herein, are not necessarily excluded from the scope of the invention, the scope of the invention being defined by the following claims.

1. Apparatus for transferring a logic signal from a first unit to a second unit, the apparatus comprising:
a first conductor for transferring the logic signal;
a complementary unit for forming the complement of the logic signal;
a second conductor coupled to the complementary unit for transferring the logic signal complement; and
a verification unit coupled to the first and second conductor, the verification unit using the signals transferred by the first and second conductor to reconstitute the logic signal.

2. The apparatus as recited in claim 1 wherein the verification unit issues a preselected signal when the verification unit can not reconstruct the logic signal.

3. The apparatus as recited in claim 1 wherein the verification unit includes a logic AND gate, the first conductor coupled to a first terminal of the logic AND gate, the second conductor being coupled to an inverting terminal of the logic AND gate, the output terminal of the logic AND gate providing the logic signal in the absence of error.

4. The apparatus as recited in claim 3 wherein the output of the logic AND gate has a predetermined value when an error is detected.

5. The apparatus as recited in claim 1 wherein the verification unit includes a logic EXCLUSIVE NOR gate, the first conductor being coupled to a first input terminal of the logic EXCLUSIVE NOR gate, the second conductor being coupled to a second input terminal of the logic EXCLUSIVE NOR gate, the output terminal of the logic EXCLUSIVE NOR gate providing the preselected signal when an error in the transmission of the logic signal is identified.

6. The apparatus as recited in claim 1 wherein the first and second conductors are part of a bus.

7. A method for transferring a logic signal over a bus, the method comprising;
transferring both the logic signal and a complement of the logic signal over the bus; and
combining the transferred logic signal and the transferred complement of the logic signal to provide the logic signal, the logic signal being provided in the absence of error in the transfer of the logic signal and complement of the logic signal.

8. The method as recited in claim 7 further comprising generating a preselected signal when the logic signal and the transferred complement of the logic signal can not be combined to form the logic signal.

9. The method as recited in claim 7 wherein transferring step includes transferring the transferred logic signal and the transferred complement of the logic signal over separate conductors.

10. The automotive system for exchanging logic signals in an automotive unit, the system comprising:
a central processing unit;
at least one peripheral unit; and
a bus coupling the central processing unit and the peripheral unit, the bus including a first and a second conductor;
wherein a signal transmitting unit includes an a logic signal inverting device coupled to the second conductor, the transmitting unit applying a logic signal to the first conductor and to an input terminal of the logic signal inverting device;
wherein a signal receiving unit includes combining unit, the combining unit combining the signals on the first and second conductor to provide the logic signal when an error has not occurred to the signals transmitted by the first and second conductors.

11. The system as recited in claim 10 wherein the unit for combining includes a component for generating a preselected signal when an error has occurred in the transmission of a signal on one of the first or second conductors.

12. The system as recited in claim 10 wherein the combining unit includes a logic AND gate, the first conductor being coupled to a first input terminal of logic AND gate, the second conductor being coupled to a second and inverting input terminal of the logic AND gate.

13. The system as recited in claim 11 wherein the component is a logic EXCLUSIVE NOR gate, the first conductor being coupled to a first input terminal of the logic EXCLUSIVE NOR gate, the second conductor being coupled to a second input terminal of the logic EXCLUSIVE NOR gate.
